(19) United States
(12) Patent Application Publication
(10) Pub. No.: US 2014/0015541 A1
(43) Pub. Date: Jan. 16, 2014

(54) ELECTRIC FIELD MEASURING DEVICE

(71) Applicants: Takeshi Sakai, Chiyoda-ku (JP); Masahito Mure, Chiyoda-ku (JP)

(72) Inventors: Takeshi Sakai, Chiyoda-ku (JP); Masahito Mure, Chiyoda-ku (JP)

(73) Assignee: Sumitomo Osaka Cement Co., Ltd., Chiyoda-ku, Tokyo (JP)

(21) Appl. No.: 14/008,302

(22) PCT Filed: Mar. 14, 2012
(86) PCT No.: PCT/JP2012/056561

§ 371 Date: Sep. 27, 2013

(30) Foreign Application Priority Data
Mar. 29, 2011 (JP) 2011-071813

(51) Int. Cl. G01R 31/00

(52) U.S. Cl. CPC G01R 31/001
USPC 324/537

(57) ABSTRACT

In the electric field measuring device, a DC bias circuit applying a DC bias voltage to an optical intensity modulator is disposed in an area, and a DC bias control portion controlling a DC bias voltage is disposed outside the area. An electrical signal of a DC bias voltage which is output from the DC bias control portion is converted into an optical signal by an electrical-optical converter (E/O) so as to be introduced into the area via an optical fiber, and the optical signal is converted into an electrical signal by an optical-electrical converter (O/E) disposed in the area such that the electrical signal is input to the DC bias circuit.

### TECHNICAL FIELD

The present invention relates to an electric field measuring device, and particularly to an electric field measuring device which is used in an analog optical transmission technique or the like for an electromagnetic field measuring field such as measurement of radiated electromagnetic wave noise of an electronic apparatus or the like, evaluation of an electromagnetic wave measuring facility such as an anechoic chamber, and evaluation of an antenna.

### BACKGROUND ART

A measurement of radiated electromagnetic wave noise is performed in measurement circumstances in which electromagnetic waves from objects other than a measurement target are suppressed using a facility such as an anechoic chamber. For this reason, a signal received by a reception antenna inside the anechoic chamber is transmitted to an adjacent measurement chamber, and is measured by a measurement unit installed therein.

In recent years, with the high speed operations of electronic apparatuses, electromagnetic noise has increased in a frequency, and thus has been required to be evaluated with a frequency of over 1 GHz, or over 10 GHz depending on cases. The present applicant has proposed an optical transmission method of a signal received by a reception antenna, using an optical modulator having a Mach-Zehnder type optical waveguide or an optical fiber transmission device such as an optical fiber in PTL 1.

In addition, there are many cases where a noise level generated from a device to be measured is an unexpected level, and various measurements are performed using the same facility. For this reason, a range of a level of a transmitted signal is very wide, and there is an intensity difference of several tens of dB in some cases. Therefore, in order to easily determine such abnormalities of the input level, a new electric field measuring device has been proposed in PTL 2.

In PTL 1 or 2, an electrical signal detected by an antenna is transmitted using an optical modulator including a Mach-Zehnder type optical waveguide, therefore it is necessary to maintain a DC bias of the optical modulator in an appropriate state at all times. For this reason, a DC signal or a DC voltage required to control the DC bias is introduced into an area for measuring an electromagnetic wave by using a power supply line.

The supply of a DC voltage or the like using the power supply line has less influence on a measurement of an electromagnetic wave than in a case of the supply of an AC signal, but noise tends to be generated from the power supply line itself, and there is also concern that noise outside the measurement area may enter the measurement area via the power supply line. This causes accuracy or reliability of the measurement to be lowered.

### CITATION LIST

### Patent Literature

### PTL 1: Japanese Laid-open Patent Publication No. 2010-127777

PTL 2: Japanese Patent Application No. 2010-36770 (filed on Feb. 23, 2010)

### SUMMARY OF INVENTION

### Technical Problem

An object of the present invention is to provide an electric field measuring device which solves the above-described problems and thus improves accuracy and reliability of electric field measurement in a facility such as an anechoic chamber by eliminating a power supply line led into a measurement area.

### Solution to Problem

In order to solve the above-described problems, the present invention has the following technical features.

(1) An electric field measuring device which measures an electric field intensity of an electromagnetic wave generated from equipment under test disposed in an area for detecting an electromagnetic wave, comprises an antenna, an RF amplifier amplifying an output signal from the antenna, an optical intensity modulator including a Mach-Zehnder type optical waveguide which performs optical modulation on the basis of an output signal from the RF amplifier, and a DC bias circuit applying a DC bias voltage to the optical intensity modulator, disposed in the area; and a light source portion, a light receiving portion receiving output light from the optical intensity modulator, a DC bias control portion controlling a DC bias voltage supplied to the optical intensity modulator on the basis of an intensity variation of an output signal from the light receiving portion, and a measurement unit measuring the electric field intensity on the basis of an output signal from the light receiving portion, disposed outside the area, in which a light wave is introduced into the optical intensity modulator from the light source portion via an optical fiber, in which a light wave is led out to the light receiving portion from the optical intensity modulator via an optical fiber, and, in which an electrical signal of a DC bias voltage output from the DC bias control portion is converted into an optical signal by an electrical-optical converter so as to be introduced into the area via an optical fiber, and the optical signal introduced into the area is converted into an electrical signal by an optical-electrical converter disposed in the area such that the electrical signal converted by the optical-electrical converter is input to the DC bias circuit.

(2) In the electric field measuring device set forth in (1), a DC power source driving the RF amplifier and the DC bias circuit is disposed in the area.

(3) In the electric field measuring device set forth in (1), an optical fiber connecting the optical intensity modulator to the light receiving portion is also used as an optical fiber connecting the electrical-optical converter to the optical-electrical converter, and wavelength demultiplexing and multiplexing elements are disposed around both ends of the optical fiber connecting the optical intensity modulator to the light receiving portion.

(4) In the electric field measuring device set forth in (1), a signal intensity detector detecting whether or not an intensity of an output signal from the antenna exceeds a predetermined level, a signal generator generating a detection result signal on the basis of a detection result from the signal intensity detector, and a multiplexer multiplexing an output signal from the RF amplifier, the detection result signal, and a DC bias voltage, are disposed in the area, and the optical intensity modulator performs optical modulation on the basis of an output signal from the multiplexer, and a display unit detecting a signal based on the detection result signal from an output of the light receiving portion and displaying the detection result is disposed outside the area.

(5) The electric field measuring device set forth in (4) further comprises an attenuator attenuating an intensity of an output signal from the antenna on the basis of a result from the signal intensity detector.

(6) The electric field measuring device set forth in (4) further comprises an RF amplification control portion controlling an output of the RF amplifier on the basis of a result from the signal intensity detector.

### Advantageous Effects of Invention

As in the electric field measuring device of the present invention, an electrical signal of a DC bias voltage which is output from the DC bias control portion is converted into an optical signal by the electrical-optical converter so as to be introduced into the area via an optical fiber, and the optical signal introduced into the area is converted into an electrical signal by the optical-electrical converter disposed in the area such that the electrical signal converted by the optical-electrical converter is input to the DC bias circuit. Therefore, since a line path led into the measurement area from the outside of the measurement area is only the optical fiber, it is possible to suppress noise from penetrating into the area from the outside of the area, thereby improving accuracy and reliability of electric field measurement.

### BRIEF DESCRIPTION OF THE DRAWINGS

FIG. 1 is a schematic diagram illustrating an electric field measuring device according to the present invention.

FIG. 2 is a diagram illustrating configurations of a head unit 2 and a controller unit 6 shown in FIG. 1.

FIG. 3 is a diagram illustrating an application example of the configurations of the head unit 2 and the controller unit 6 shown in FIG. 1.

### DESCRIPTION OF EMBODIMENTS

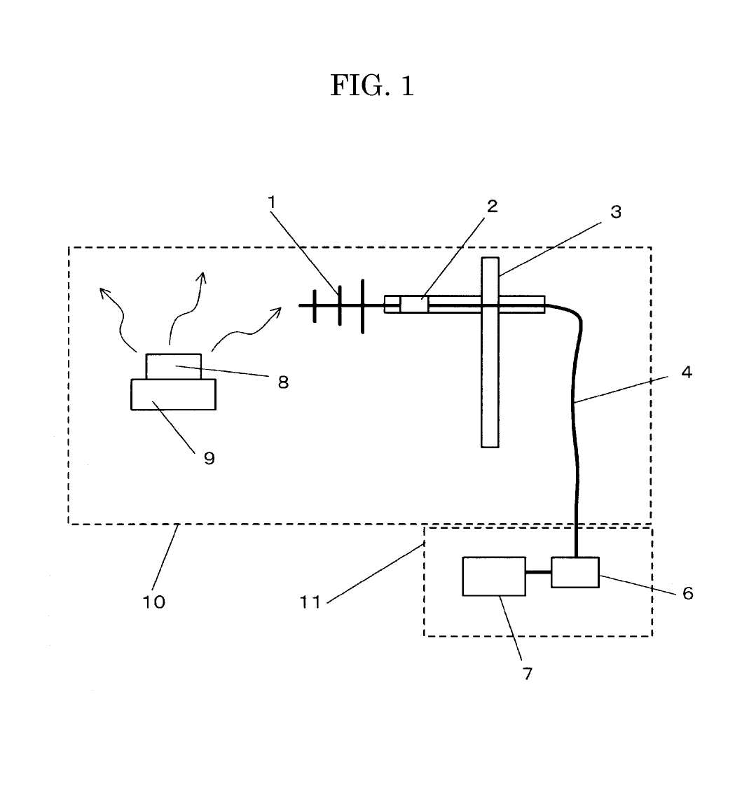

Hereinafter, the present invention will be described in detail using preferred embodiments. FIG. 1 is a diagram schematically illustrating a configuration of an electric field measuring device according to the invention. An electric field intensity of an electromagnetic wave (indicated by the wavy arrow) generated from equipment under test (EUT) 8 disposed in an area for detecting an electromagnetic wave, such as an anechoic chamber 10, is measured. The reference numeral 9 indicates a mounting stand on which the equipment under test is placed such as a turntable.

The “area for detecting an electromagnetic wave” in the present invention is not limited to the anechoic chamber, but refers to a space such as an open site in which the equipment under test is disposed in order to detect an electromagnetic wave generated from the equipment under test. In addition, the outside of the “area for detecting an electromagnetic wave” means an area not interfering with the measurement of an electromagnetic wave generated from the equipment under test, and may include the outside of the anechoic chamber, a place sufficiently apart from the equipment under test, and a space such as a measurement chamber described later in which a body portion or a measurement unit is accommodated and which blocks an electromagnetic wave generated from an apparatus from leaking into the “area for detecting an electromagnetic wave”. Hereinafter, the anechoic chamber and the measurement chamber will be described as an example.

An antenna 1 and a head unit 2 including an optical intensity modulator including a Mach-Zehnder type optical waveguide are disposed inside the anechoic chamber 10. An output signal of the antenna 1 is applied to a modulation electrode of the optical intensity modulator and changes the refractive index of the Mach-Zehnder type optical waveguide, as described in PTL 1. Due to this change in the refractive index, a phase of a light wave propagating through the optical waveguide is modulated and an optical intensity of the light wave output from the Mach-Zehnder type optical waveguide is modulated. The reference numeral 3 indicates antenna positioning means for locating the antenna 1 at a predetermined position.

A traveling-wave type optical modulator in which an optical waveguide and a modulation electrode are formed in a substrate having an electro-optical effect can be suitably used as the optical intensity modulator. The substrate having an electro-optical effect may be made of, for example, lithium niobate, lithium tantalate, lead lanthanum zirconate titanate (PLZT), quartz materials, or the like. The Mach-Zehnder type optical waveguide may be formed on the substrate having an electro-optical effect by diffusing Ti and the like on the substrate surface using a thermal diffusion method or a proton exchange method or by forming a ridge-shaped convex portion thereon. The modulation electrode includes a signal electrode and a ground electrode to which an output signal of the antenna is applied, and may be formed on the substrate by using a method of forming Ti and Au electrode pattern, a gold plating method, and the like. In addition, a buffer layer of a dielectric of SiO₂ may be formed on the substrate surface having the optical waveguide formed thereon as necessary, thereby suppressing the absorption or scattering of a light wave with the electrode formed on the optical waveguide.

In a method of adjusting a bias point of the optical intensity modulator, it is possible to adjust the bias point of the optical intensity modulator by applying a voltage, which is obtained by superimposing a DC bias voltage on an output voltage of the antenna, to the above-described modulation electrode. A bias point control electrode other than the modulation electrode may be separately formed and the DC bias voltage may be applied to the electrode.

A measurement chamber 11 is disposed outside of the anechoic chamber 10 so as to be adjacent to the anechoic chamber 10. A controller unit 6 of the measuring device controlling the head unit 2 and a measurement unit 7 such as an EMI receiver are disposed in the measurement chamber 11. The head unit 2 and the controller unit 6 are connected to each other via only an optical fiber 4.

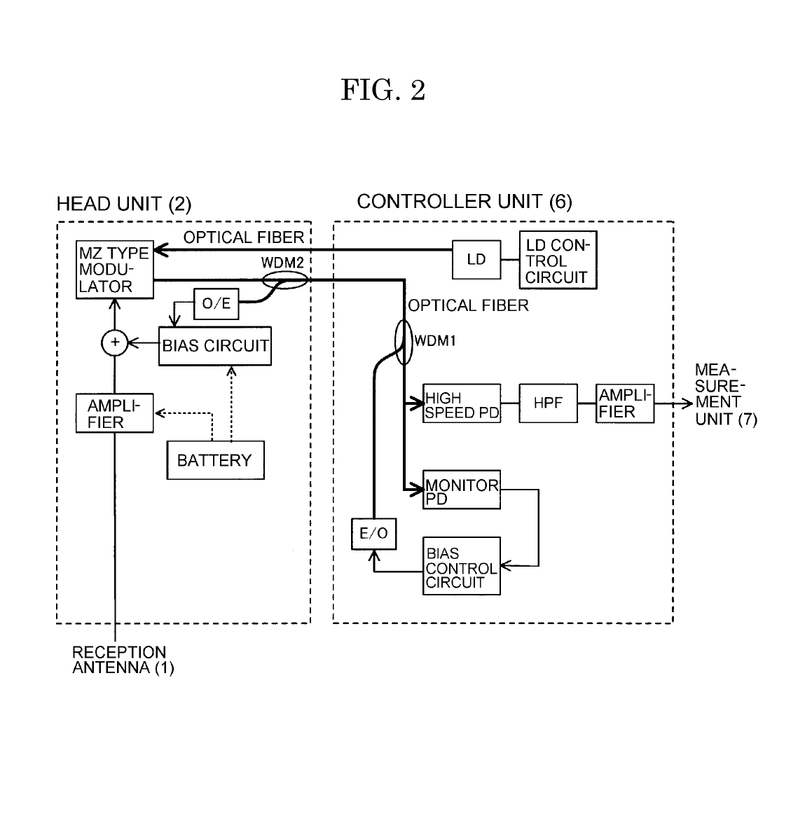

FIG. 2 is a diagram illustrating the configurations of the head unit 2 and the controller unit 6 more in detail. An output signal (30 MHz or more) from the reception antenna is introduced into the head unit 2 and is input to an amplifier. The amplifier is an RF amplifier which amplifies the output signal from the antenna.

The output signal from the amplifier which is an RF amplifier is multiplexed with a DC bias voltage from a DC bias circuit described later. A multiplexer is indicated by the sign + in the figure. There is a disposition of an optical intensity modulator (MZ type modulator) having the Mach-Zehnder type optical waveguide which performs optical modulation on the basis of an output signal from the multiplexer.

A semiconductor laser (LD) which is a light source portion and an LD control circuit which is a control circuit driving the semiconductor laser are provided in the controller unit 6, and continuous (CW) light with a specific level is output from the semiconductor laser and is transmitted via the optical fiber so as to be input to the MZ type modulator of the head unit 2.

In addition, a light receiving portion (a high speed PD and a monitor PD) receiving output light from the MZ type modulator which is an optical intensity modulator is provided in the controller unit 6. In FIG. 2, the light receiving portion includes two light receiving elements (PD), but may include a single PD, and may separate an output signal from the PD into a high frequency signal of 30 MHz or more and a low frequency signal of, for example, below 30 MHz which is a signal band related to DC bias control.

The high speed PD detects a signal of 30 MHz or more corresponding to the output signal from the antenna, and a signal which has passed through a high-pass filter (HPF) is amplified by an amplifier and is then introduced into the measurement unit 7.

A low frequency signal of, for example, below 30 MHz is output as a signal of the monitor PD and is then input to the DC bias control circuit. The bias control circuit which is a DC bias control portion determines a DC bias voltage which is supplied to the optical intensity modulator on the basis of an intensity change of an output signal from the monitor PD which is a light receiving portion.

An electrical signal of the DC bias voltage output from the DC bias control portion is converted into an optical signal by an electrical-optical converter (E/O). The optical signal is introduced into the measurement area via the optical fiber so as to be converted into an electrical signal by an optical-electrical converter (O/E) disposed in the measurement area. In addition, the electrical signal is input to the DC bias circuit such that a DC bias based on an output from the DC bias control portion is applied to the optical modulator.

An optical fiber used for DC bias control may be provided separately from the optical fiber connecting the optical modulator to the monitor PD, but the former optical fiber may be also used as the latter optical fiber in order to reduce the number of provided optical fibers as shown in FIG. 2. In this case, it is necessary that wavelength demultiplexing and multiplexing elements (WDM1 and WDM2) or circulators be disposed at end parts of the optical fiber, and output light from the optical modulator be separated from light wave related to DC bias control in a traveling direction of the light wave with high efficiency.

In addition, an RF amplifier which is an amplifier and a DC power source which is a battery for driving the bias circuit are disposed in the head unit (2). The DC power source does not generate noise such as an AC signal and thus does not impair accuracy or reliability of electric field measurement.

A relation curve (Vπ modulation curve) of a driving voltage and a light intensity output of the optical intensity modulator shows a sinusoidal function, and thus a half point of the maximum optical intensity is typically a bias point adjustment center. Naturally, a bias central point is not limited to the half point, and may employ an intensity level lower than the half point by keeping a balance with shot noise of the monitor PD.

Before the electric field measurement is performed, bias point adjustment is performed as necessary. Specifically, a light wave is introduced into the optical intensity modulator from the LD of the light source portion so as to sweep a bias voltage applied to the optical intensity modulator, a value at which an output level of monitor light is the highest is measured so as to find, for example, a bias voltage indicating a half value of the highest value.

In a case where the bias point is adjusted in this way, an AC signal such as a low frequency signal which is frequently used for bias point control of an optical modulator in the related art is unnecessary, and thus it is possible to further suppress noise radiation inside the anechoic chamber. Of course, in a range of not inhibiting the electric field measurement, a bias point may be controlled through superimposition of an AC signal such as a low frequency signal.

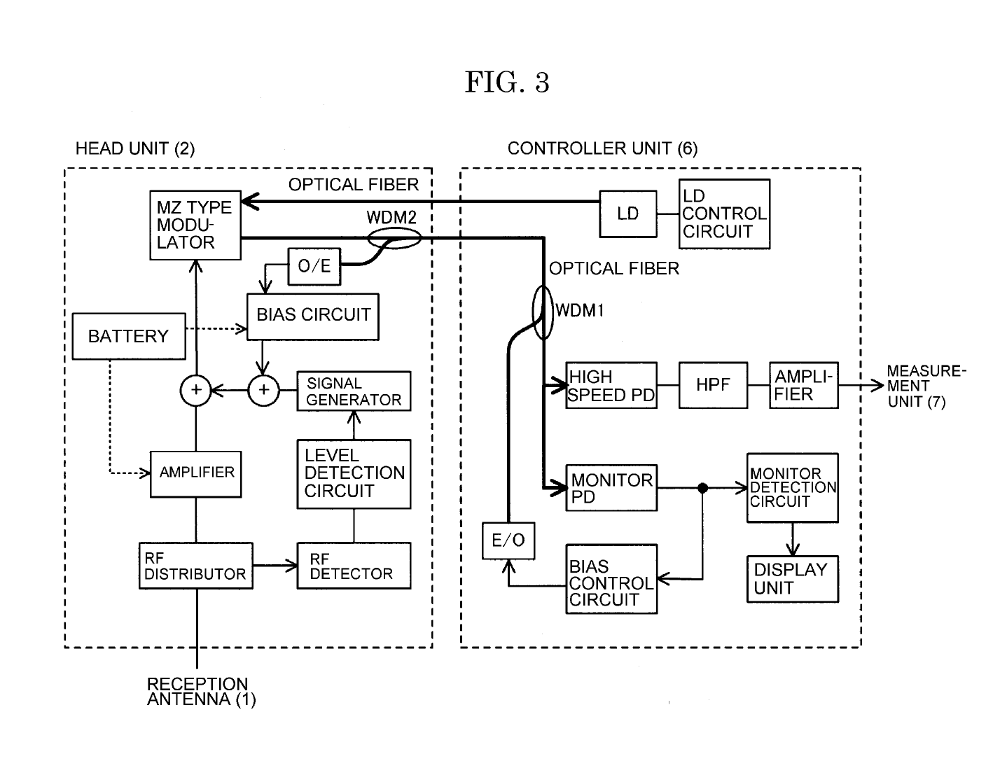

Next, an application example of the head unit 2 and the controller unit 6 will be described with reference to FIG. 3. A feature of the invention shown in FIG. 3 is that means for monitoring a signal level received by an antenna, disclosed in PTL 2, is additionally provided.

An output signal (30 MHz or more) from the reception antenna is introduced into the head unit 2, and the output signal is distributed to an amplifier and an RF detector by an RF distributor. The RF detector detects an intensity of the output signal and introduces the detected signal into a level detection circuit so as to detect whether or not the intensity of the output signal exceeds a predetermined level. The RF detector and the level detection circuit are combined so as to form a signal intensity detector. A signal generator is provided which generates a detection result signal on the basis of a detection result from the signal intensity detector. For example, in a case where the optical modulator exceeds a certain level causing distortion, the signal generator performs intensity modulation with a low frequency signal (below 20 MHz) having bands other than the band of the output signal from the reception antenna.

The output signal from the amplifier which is an RF amplifier, the detection result signal from the signal generator, and a DC bias voltage from the DC bias circuit are multiplexed. There is a disposition of an optical intensity modulator (MZ type modulator) which performs optical modulation on the basis of an output signal from the multiplexer.

A low frequency signal of below 30 MHz is output as a signal of the monitor PD, and is branched into two by a branching element such as a Bias-T circuit so as to be respectively output to a DC bias control circuit and a monitor detection circuit. In addition, in this case, a pass filter for a specific frequency band which allows a signal related to DC bias control of the optical modulator to pass therethrough may be inserted into the front stage of the DC bias control circuit, and a pass filter for another specific frequency band which allows the detection result signal generated from the signal generator to pass therethrough may be inserted into the front stage of the monitor detection circuit. Further, these pass filters may be built in the DC bias control circuit or the monitor detection circuit.

The detection result signal generated from the signal generator is detected from the output signal from the monitor PD which is a light receiving portion by the monitor detection circuit. For example, only a low frequency signal (below 30 MHz) generated when the output signal from the reception antenna exceeds a predetermined level is detected, and an excessive input state is displayed on a display device on the basis of the detection result.

In the electric field measuring device of the present invention, an intensity of an output signal from the antenna, which is input to the RF amplifier or the optical modulator, may be automatically adjusted, thereby suppressing output saturation or distortion in a transmission device.

A variable attenuator which attenuates an intensity of an output signal from the reception antenna is disposed between the reception antenna and the RF distributor, or between the RF distributor and the amplifier. In addition, as in FIG. 3, the variable attenuator may be controlled so as to adjust a level of a signal which is input to the RF amplifier or the optical intensity modulator when an intensity of an output signal from the reception antenna exceeds a predetermined level on the basis of a result from the signal intensity detector including the RF detector and the level detection circuit.

In addition, a constituent element, which controls an output of the RF amplifier on the basis of a result from the signal intensity detector, may be provided as an RF amplification control portion such that the variable attenuator is omitted.

As described above, in a case where an intensity of an output signal from the antenna is automatically adjusted, a level of the output signal which is input to the measurement unit connected to the controller unit varies, and thus it is difficult for the measurement unit to determine whether the variation is caused by the automatic adjustment or by a reduction in a level of the received electromagnetic wave itself. In order to remove this inconvenience, a signal indicating an adjusted level may also be output as a part of a detection result signal from the signal generator so as to be transmitted to the controller unit in a case where a signal output is adjusted using the variable attenuator or the RF amplifier. The controller unit may extract the signal related to the adjusted level from the detection result signal, so as to perform calibration or the like of a level of the output signal from the measurement unit.

In addition, a battery which is a DC power source may be incorporated as a power source which supplies power to various components of the head so as to be driven. The battery may be used as a driving source of not only the amplifier which is an RF amplifier and the DC bias circuit but also the RF detector and the level detection circuit forming the signal intensity detector, the signal generator, and the like.

### INDUSTRIAL APPLICABILITY

As described above, according to the present invention, it is possible to provide an electric field measuring device which improves accuracy and reliability of electric field measurement in a facility such as an anechoic chamber by eliminating a power supply line led into a measurement area.

### REFERENCE SIGNS LIST

1 ANTENNA

2 HEAD UNIT

4 OPTICAL FIBER

6 CONTROLLER UNIT

7 MEASUREMENT UNIT

8 EQUIPMENT UNDER TEST

1. An electric field measuring device which measures an electric field intensity of an electromagnetic wave generated from equipment under test disposed in an area for detecting an electromagnetic wave, comprising:
an antenna, an RF amplifier amplifying an output signal from the antenna, an optical intensity modulator including a Mach-Zehnder type optical waveguide which performs optical modulation on the basis of an output signal from the RF amplifier, and a DC bias circuit applying a DC bias voltage to the optical intensity modulator, disposed in the area; and
a light source portion, a light receiving portion receiving output light from the optical intensity modulator, a DC bias control portion controlling a DC bias voltage supplied to the optical intensity modulator on the basis of an intensity variation of an output signal from the light receiving portion, and a measurement unit measuring the electric field intensity on the basis of an output signal from the light receiving portion, disposed outside the area,
wherein a light wave is introduced into the optical intensity modulator from the light source portion via an optical fiber,
wherein a light wave is led out to the light receiving portion from the optical intensity modulator via an optical fiber, and
wherein an electrical signal of a DC bias voltage output from the DC bias control portion is converted into an optical signal by an electrical-optical converter so as to be introduced into the area via an optical fiber, and the optical signal introduced into the area is converted into an electrical signal by an optical-electrical converter disposed in the area such that the electrical signal converted by the optical-electrical converter is input to the DC bias circuit.

2. The electric field measuring device according to claim 1, wherein a DC power source driving the RF amplifier and the DC bias circuit is disposed in the area.

3. The electric field measuring device according to claim 1, wherein an optical fiber connecting the optical intensity modulator to the light receiving portion is also used as an optical fiber connecting the electrical-optical converter to the optical-electrical converter, and wavelength demultiplexing and multiplexing elements are disposed around both ends of the optical fiber connecting the optical intensity modulator to the light receiving portion.

4. The electric field measuring device according to claim 1, wherein a signal intensity detector detecting whether or not an intensity of an output signal from the antenna exceeds a predetermined level, a signal generator generating a detection result signal on the basis of a detection result from the signal intensity detector, and a multiplexer multiplexing an output signal from the RF amplifier, the detection result signal, and a DC bias voltage, are disposed in the area, and the optical intensity modulator performs optical modulation on the basis of an output signal from the multiplexer, and
wherein a display unit detecting a signal based on the detection result signal from an output of the light receiving portion and displaying the detection result is disposed outside the area.

5. The electric field measuring device according to claim 4, further comprising an attenuator attenuating an intensity of an output signal from the antenna on the basis of a result from the signal intensity detector.

6. The electric field measuring device according to claim 4, further comprising an RF amplification control portion controlling an output of the RF amplifier on the basis of a result from the signal intensity detector.
